(19) United States
(12) Patent Application Publication
(10) Pub. No.: US 2026/0198343 A1
(43) Pub. Date: Jul. 9, 2026

(54) RELIABILITY FABRICATION OF THROUGH VIAS FOR GLASS CORE INTEGRATED CIRCUIT PACKAGES

(71) Applicant: Intel Corporation, Santa Clara, CA (US)

(72) Inventors: Sameer Paital, Mesa, AZ (US); Whitney Bryks, Tempe, AZ (US); Jeremy Ecton, Gilbert, AZ (US); Srinivas Pietambaram, Chandler, AZ (US); Rahul Manepalli, Chandler, AZ (US); Kristof Darmawikarta, Chandler, AZ (US); Hiroki Tanaka, Gilbert, AZ (US); Joseph Peoples, Gilbert, AZ (US); Joshua Stacey, Chandler, AZ (US); Jieying Kong, Chandler, AZ (US); Dilan Seneviratne, Phoenix, AZ (US); Shaojiang Chen, Gilbert, AZ (US); Bohan Shan, Chandler, AZ (US); Gang Duan, Chandler, AZ (US); Brandon Marin, Gilbert, AZ (US); Suddhasattwa Nad, Chandler, AZ (US)

(73) Assignee: Intel Corporation, Santa Clara, CA (US)

(21) Appl. No.: 19/011,337

(22) Filed: Jan. 6, 2025

(51) Int. Cl. H01L 23/498; H01L 21/48; H01L 23/15

(52) U.S. Cl. CPC H10W 70/635; H10W 70/095; H10W 70/69; H10W 70/692

(57) ABSTRACT

Through glass via structures including via metallizations and gaps between the via metallizations and sidewalls of openings in the glass substrate, and related packages, apparatuses, and systems are discussed. Glass substrates for use in an integrated circuit package have a first surface, an opposing second surface, and an opening extending between the first and second surfaces. A sacrificial material is coated on a sidewall of the opening and a via metallization is formed within the sacrificial material. The sacrificial material is removed, leaving one or more gaps between the via metallization and the sidewall of the opening to at least partially decouple the via metallization and the glass substrate.

### BACKGROUND

Higher performance, lower cost, increased miniaturization, greater packaging density, and increased product flexibility of integrated circuit (IC) devices are ongoing goals of the electronics industry. IC packaging is a stage of semiconductor or IC device fabrication in which an IC that has been monolithically fabricated on a chip (or die) is assembled into a package that protects the IC chip from physical damage and communicatively connects the IC to other packaged IC chips and/or a scaled host component, such as a package substrate, or a printed circuit board. Multiple chips can be co-assembled, for example, into a multi-die package. Some package architectures include an IC die attached to a glass substrate and coupled to electrically conductive through-glass vias (TGVs) extending through the glass substrate.

Glass substrates have advantages such as low dielectric loss, high thermal stability, and improved surface planarity and surface quality. However, glass core failures such as cracks are observed due to high stress in the TGV from copper seed/glass interface during thermal processing. For example, TGVs generate stress due to the coefficient of thermal expansion (CTE) mismatch between glass and plated copper TGVs. This is accentuated by high-temperature processing (e.g. >250 C) since the heated copper expands, which stresses the glass, and upon cooling the copper shrinks more than the glass and leaves residual tensile stress in the glass, which, in turn, compromises its strength under bending modes.

Current solutions for these problems include using higher CTE glass, using via-in-vias where an opening is plugged with a dielectric material and the metal via is formed within the dielectric material, and using conformal plating and backfill with dielectric. However, these solutions have drawbacks including higher CTE glass having higher dopant concentrations and lower quality, loss of metal via size and density, and sacrifice of metal via volume, respectively. It is with respect to these and other considerations that the present improvements have been needed. Such improvements may become critical as the desire to deploy high-performance IC packages in various devices and systems becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating example methods for fabricating and assembling glass substrate structures having one or more air gaps between a through glass via metallization and a sidewall of an opening in the glass substrate;

FIGS. 2, 3, 4, 5, 6, 7, 8, 9, and 10 are illustrations of cross-sectional side views of glass substrate structures as the methods of FIG. 1 are practiced to form air gaps between a through glass via metallization and a sidewall of an opening in the glass substrate by removing a sacrificial layer through an overlying polymeric material;

FIGS. 11, 12, 13, 14, 15, 16, 17, 18, 19, and 20 are illustrations of cross-sectional side views of glass substrate structures as the methods of FIG. 1 are practiced to form air gaps between a through glass via metallization and a sidewall of an opening in the glass substrate by removing an exposed sacrificial layer and optional subsequent backfill of a dielectric material;

FIGS. 21, 22, 23, 24, 25, 26, 27, and 28 are illustrations of cross-sectional side views of glass substrate structures as the methods of FIG. 1 are practiced to form air gaps between a through glass via metallization and a sidewall of an opening in the glass substrate by removing a sacrificial layer from a bottom-up filled via metallization;

FIGS. 29, 30, and 31 are illustrations of cross-sectional side views of package structures as the methods of FIG. 1 are practiced to assemble a package assembly having a glass substrate with air gaps between a through glass via metallization and a sidewall of an opening in the glass substrate;

FIG. 32 illustrates exemplary systems employing an IC assembly including a glass core substrate with one or more air gaps between a through glass via metallization and a sidewall of an opening in the glass substrate; and

FIG. 33 is a block diagram of a computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. Herein, the term “predominantly” indicates not less than 50% of a particular material or component while the term “substantially pure” indicates not less than 99% of the particular material or component and the term “pure” indicates not less than 99.9% of the particular material or component. Unless otherwise indicated, such material percentages are based on atomic percentage. Herein the term concentration is used interchangeably with material percentage and also indicates atomic percentage unless otherwise indicated.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direction contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Apparatuses, systems, and methods are described herein related to fabrication of through glass vias within openings of a glass core substrate with improved reliability by forming the through glass via metallization within a sacrificial layer on a sidewall of the opening, and subsequently removing the sacrificial layer.

As described above, current package architectures may include one or more IC dies attached to a glass substrate and coupled to electrically conductive through-glass vias (TGVs) extending through the glass substrate. For example, the increasing demand for multichip packaging, tighter bump pitches, line space scaling for higher density interconnects, larger form factors, and thinner total package thickness, cause prior organic cores to become a limiter, which can potentially be overcome using glass core substrates. Glass cores provide mechanical benefit (e.g., reduced warpage, smaller thickness variation) and design flexibility (e.g., tighter through hole pitch, finer core routing). However, current fabrication techniques have difficulties including glass core failures due to high mechanical stresses at the copper seed/glass interface during thermal processing as well as protrusion of the via metallization during thermal processing. In particular, the high coefficient of thermal expansion (CTE) mismatch between the via metallization and the glass core cause difficulties when typical copper seed and plating techniques are used.

Embodiments discussed herein provide for gaps between the via metallization and the sidewall of the glass core within the opening to mitigate the CTE mismatch and reduce stress on the glass core, which reduces failures and improves process reliability. As used herein, the term gap indicates a region of separation between two components that may be filled with air (or partially filled or voided when vacuum is pulled during seal) such as the ambient present during the formation of the gap and/or when the gap was sealed and/or any outgassing or leakage into the gap. For example, the term air gap is indicative of a gap between components filled with the gas(es) pertinent to the gap, as used in the art. The air gaps or, simply, gaps act as a boundary between the glass substrate sidewall and the via metallization to improve electrical performance and prevent plastic deformation of the via metallization (i.e., copper) after experiencing thermal cycles (heating from room temperature to 300° C. and cooling back to room temperature) inherent in the packaging process. Other advantages will be evident based on the following disclosure.

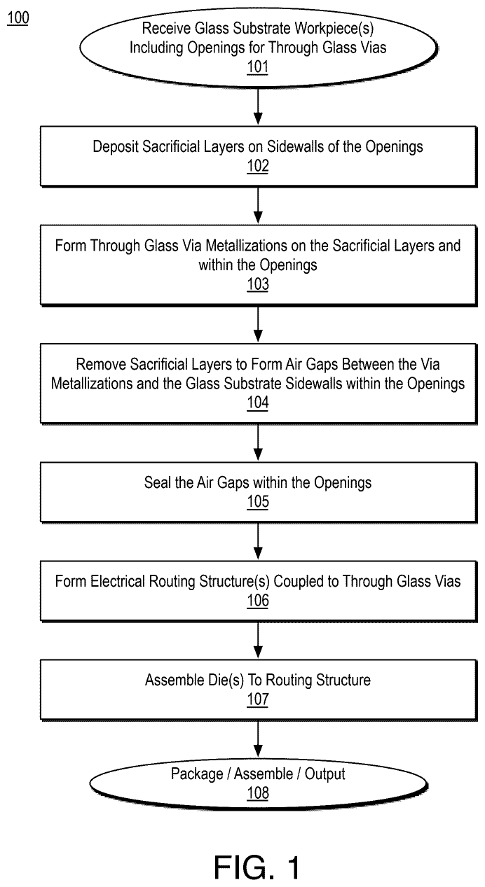

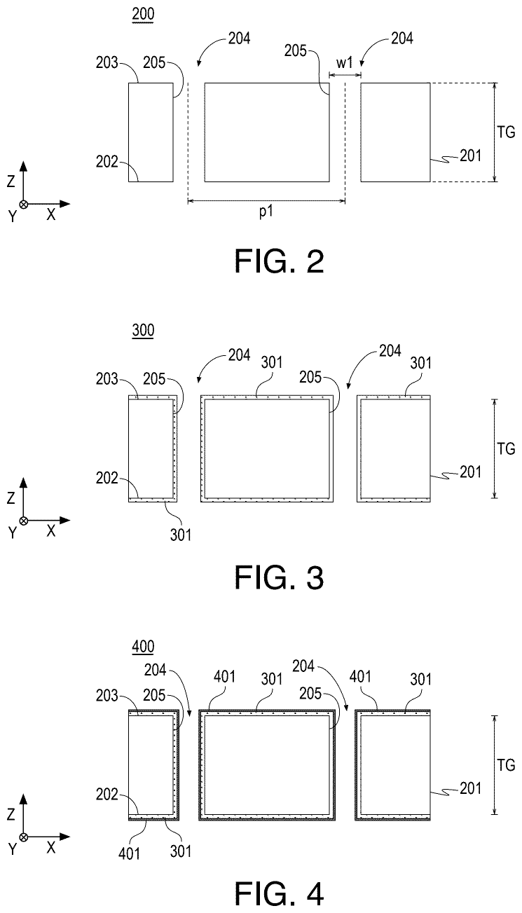

FIG. 1 is a flow diagram illustrating example methods 100 for fabricating and assembling glass substrate structures having one or more air gaps between a through glass via metallization and a sidewall of an opening in the glass substrate, arranged in accordance with at least some implementations of the present disclosure. For example, methods 100 may be implemented to fabricate any glass substrates structures, package structures, or assemblies discussed herein. In the illustrated embodiment, methods 100 include one or more operations as illustrated by operations 101-108. However, embodiments herein may include additional operations, certain operations being omitted, or operations being performed out of the order provided. FIGS. 2-31 illustrate structures and components as methods 100 are practiced.

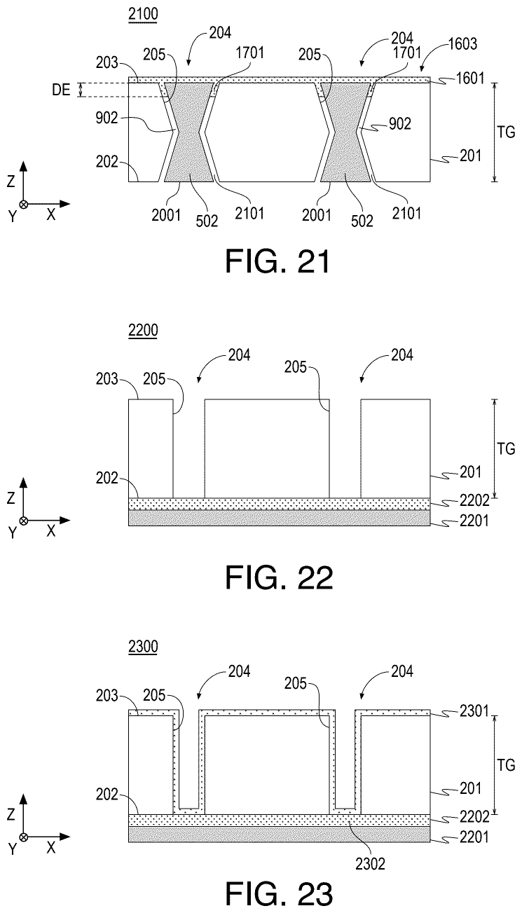

FIGS. 2, 3, 4, 5, 6, 7, 8, 9, and 10 are illustrations of cross-sectional side views of glass substrate structures as methods 100 are practiced to form air gaps between a through glass via metallization and a sidewall of an opening in the glass substrate by removing a sacrificial layer through an overlying polymeric material, arranged in accordance with at least some implementations of the present disclosure. FIGS. 11, 12, 13, 14, 15,16, 17, 18, 19, and 20 are illustrations of cross-sectional side views of glass substrate structures as methods 100 are practiced to form air gaps between a through glass via metallization and a sidewall of an opening in the glass substrate by removing an exposed sacrificial layer and optional subsequent backfill of a dielectric material, arranged in accordance with at least some implementations of the present disclosure. FIGS. 21, 22, 23, 24, 25, 26, 27, and 28 are illustrations of cross-sectional side views of glass substrate structures as methods 100 are practiced to form air gaps between a through glass via metallization and a sidewall of an opening in the glass substrate by removing a sacrificial layer from a bottom-up filled via metallization, arranged in accordance with at least some implementations of the present disclosure. FIGS. 29, 30, and 31 are illustrations of cross-sectional side views of package structures as methods 100 are practiced to assemble a package assembly having a glass substrate with air gaps between a through glass via metallization and a sidewall of an opening in the glass substrate, arranged in accordance with at least some implementations of the present disclosure.

Methods 100 begins at operation 101, where a workpiece such as a glass substrate including a thickness of glass and any number of holes or openings extending through the thickness of the glass is received. The workpieces may be prepared upstream of methods 100 and may be in a large panel format, a wafer format, or the like. In addition to the thickness of glass, the workpiece received at operation 101 may include one or more materials upon which electrical routing structures may be formed.

Methods 100 continue at operation 102, where a sacrificial layer or sacrificial layers are deposited on the sidewalls of the openings in the glass substrate received at operation 101. The sacrificial layer or layers may be deposited using any suitable technique or techniques such as conformal deposition techniques. For example, the sacrificial layer or layers may be formed using liquid dispense, inkjet, spin coating, dip coating, slit coating, squeegee-like coating, vacuum assisted plugging, chemical vapor deposition (CVD), or the like. The sacrificial layer or layers coat the sidewalls of the openings with a relatively thin (e.g., 10 nm to 5 μm) layer of sacrificial material leaving the bulk of the opening for later metal fill.

Methods 100 continue at operation 103, where the remainder of the opening is filled with via metallization. The via metallization may be formed using any suitable technique or techniques. In some embodiments, the via metallization is formed by providing a seed layer (e.g., a titanium seed layer or titanium-copper seed layer) on the exposed surfaces of the workpiece inclusive of the exposed surface of the sacrificial layer or layers, and a bulk fill material (e.g., copper) is formed from the seed layer using, for example, plating techniques. For example, the through glass via openings may be plated using electroless seeding, physical vapor deposition (PVD) seeding, atomic layer deposition (ALD) seeding, and then plating using, for example, electrolytic plating of copper or other conductive metals. In such contexts, there is no need for the metal seed to have good adhesion to the sacrificial material. In some embodiments, the via metallization is formed from a seed cladding or metal layer that is exposed at one end of the opening using bottom-up plating techniques. Alternatively, other conductive materials like pastes, sintered particles etc. can be used to form the via metallizations. In any case, the sacrificial layer or layers survive the metallization and provide a template for fabrication of the via metallization. Depending on the metallization strategy and processing context, chemical mechanical processing may be used to remove metallization overburden.

Methods 100 continue at operation 104, where the sacrificial layer or layers formed at operation 102 are removed to form air gaps between the via metallization and the sidewall of the opening in the glass substrate. The sacrificial layer or layers may be removed using any suitable technique or techniques such as a thermolytic decomposition process, a solvent dissolution process, or the like, depending on the material used and the component architecture at sacrificial layer removal. In some contexts, the removal may be done in parallel with a nominal via metallization anneal process, which can stabilize the grain structure of the via metallization copper. In such contexts, a relatively high temperature anneal (e.g., 200° C. to 500° C.) can anneal the via metallization and simultaneously decompose the liner. It is noted that such processing as well as subsequent thermal processing causes the via metallization to expand and the discussed air gaps mechanically decouple the via metallization from the glass substrate to reduce failures; however, the via metallization may contact the sidewalls within the openings such that multiple air gaps and contact points between the via metallization and the glass substrate are evident.

Methods 100 continue at operation 105, where the gaps formed at operation 104 and the openings are optionally sealed. In some embodiments, the gaps are formed by removing the sacrificial layer or layers through a material layer and the material layer provides the seal. In other embodiments, a material layer is formed over the openings and gaps such that a portion of the material layer fully or partially backfills the gaps. In other embodiments, a conductive pad or dielectric buildup layer may be formed over the gaps. In any context, the glass substrate includes gaps between via metallizations and the openings in which they reside. Optionally, the air gaps are sealed, and the glass substrate workpieces is then incorporated in a package assembly as discussed further herein below.

In the following, FIGS. 2-10, FIGS. 11-20, and FIGS. 21-28 illustrate exemplary flows of glass substrate structures and components as methods 100 are practiced. In such contexts, like components and structures are labeled with the same reference numbers and such like-labeled components and structures may have any characteristics (i.e., materials, dimensions, etc.) discussed with respect to any such flow.

FIG. 2 is an illustration of a cross-sectional side view of a glass substrate structure 200 including materials received for processing at operation 101 such as a glass substrate 201 having a first surface 202, an opposing second surface 203, and a thickness TG extending between first surface 202 and second surface 203, and orthogonal to both. As discussed below, IC device package structures may be advantageously fabricated upon glass substrate 201 as flatness and/or thickness control for a preform of glass is superior to that of starting substrates based on organic materials (e.g., epoxy), and costs can be significantly lower than for monocrystalline materials (e.g., silicon).

Glass substrate 201 is a solid bulk material layer that may have been previously formed into any shape in plan view (e.g., x-y plane) suitable for a packaging workpiece, such as a rectangular shape. Glass substrate 201 has a thickness TG that may vary with implementation, for example, to limit warpage while remaining thin enough to permit the formation of through glass vias. In some embodiments, thickness TG is not less than 200 μm and not more than 2000 μm. In some embodiments, thickness TG is advantageously not less than 350 μm and not more than 1000 μm such as a thickness of 400 μm.

In some embodiments, glass substrate 201 is predominantly silicon and oxygen. In some embodiments, glass substrate 201 includes at least 23 percent silicon and at least 26 percent oxygen, by weight (i.e., wt. %). Glass substrate 201 may further include one or more additives, such as, aluminum, boron, magnesium, calcium, barium, tin, sodium, potassium, strontium, phosphorus, zirconium, lithium, titanium, or zinc. In embodiments where glass substrate 201 includes at least 23 wt. % Si and at least 26 wt. % O, glass substrate 201 may further include at least 5 wt. % Al. Additives within glass substrate 201 may form suboxides (A₂O) monoxides (AO), binary oxides (AO₂), ternary oxides (ABO₃), and mixtures thereof. For example, glass substrate 201 may include AlOₓ (e.g., Al₂O₃), BOₓ (e.g., B₂O₃), MgOₓ (e.g., MgO), CaOₓ (e.g., CaO), SrOₓ (e.g., SrO), BaOₓ (e.g., BaO), SnOₓ (e.g., SnO₂), NaOₓ (e.g., Na₂O), KOₓ (e.g., K₂O), POₓ(e.g., P₂O₃), ZrOₓ (e.g., ZrO₂), LiOₓ (e.g., Li₂O), TiOₓ (e.g., TiO₂), or ZnOₓ (e.g., ZnO₂). In some embodiments, glass substrate is a BF33 glass. Depending on chemical composition, glass substrate 201 may therefore be referred to as silica, fused silica, aluminosilicate, borosilicate, or alumino-borosilicate, for example.

In some embodiments, glass substrate 201 is advantageously a bulk material of substantially homogeneous composition in contrast to a composite material that may merely include glass fillers and/or fibers. Although glass substrate 201 is substantially amorphous in some embodiments, glass substrate 201 may also have other morphology or microstructure, such as polycrystalline (e.g., nanocrystalline). In some embodiments, glass substrate 201 is rectangular in shape in plan view. However, other shapes may be used. In some embodiments, glass substrate 201 is a layer of glass having a thickness of not less than 50 μm, a first length of not less than 10 mm and a second length orthogonal to the first length of not less than 10 mm. In some embodiments, glass substrate 201 is absent any organic adhesive or other organic material. Although not depicted, one or more material layers may clad either or both of first surface 202 and second surface 203 of glass substrate 201 so that glass substrate 201 is a bulk or core layer of a multi-layered substrate. Exemplary cladding materials include inorganic materials such as silicon nitride (SiNₓ) or silicon oxynitride (SiOₓN_{y}). In other embodiments, a silicon layer (polycrystalline or monocrystalline) may clad one or both sides of glass substrate 201. Organic material layers, such as polymer dielectric materials, may also clad one or more sides of glass substrate 201. Hence, while glass substrate 201 is advantageously substantially free of organic materials (e.g., no adhesives, etc.), a workpiece may include organic within a substrate stack that includes glass substrate 201. Such claddings or build-up layers may be fabricated on glass substrate 201 as discussed herein below.

As shown, holes, through holes, or openings 204 in glass substrate 201 extend from first surface 202 to second surface 203 and through thickness TG of glass substrate 201. Furthermore, openings 204 define sidewalls 205 of glass substrate 201 that also extend from first surface 202 to second surface 203. Openings 204 may be formed using any suitable technique or techniques such as laser assisted etch techniques with a dual side etch or single side etches. Although illustrated with openings 204 having a constant width or diameter throughout thickness TG, in some embodiments, openings 204 may have a dual taper profile or a single tape profile as is shown in FIG. 11 herein below.

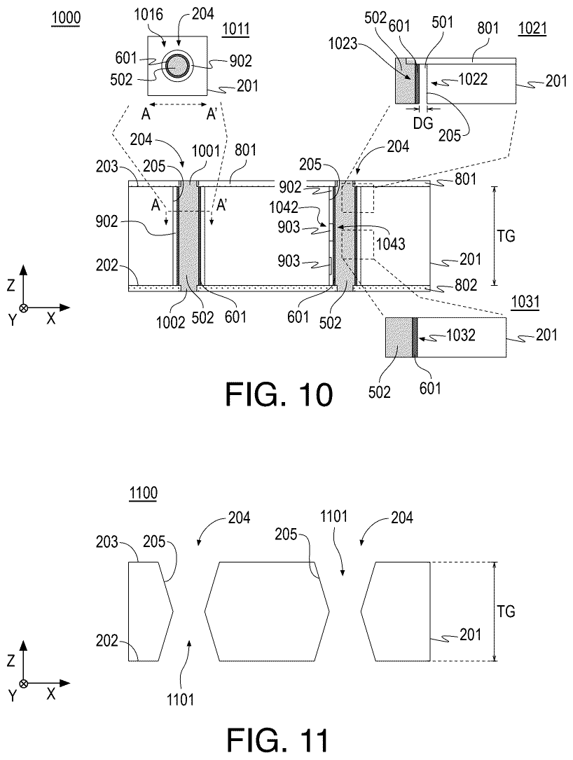

Openings 204 may have any suitable lateral cross-sectional shape in the x-y plane such as circular or oval (see FIG. 10). Openings 204 have a diameter or cross-sectional width w1 (a longest distance across opening 204 in the x-y plane). Openings 204 may have any suitable cross-sectional width w1 such as a width w1 in the range of about 15 to 80 μm. Furthermore, the thickness TG of glass substrate 201 over the width w1 of openings 204 defines an aspect ratio of openings 204. In some embodiments, the aspect ratio (AR =TG/w1) of openings 204 is not less than 5 (i.e., for a 400 μm thickness TG, opening widths w1 of not more than 80 μm). In some embodiments, the aspect ratio of openings 204 is not less than 10 (i.e., for a 400 μm thickness TG, opening widths w1 of not more than 40 μm). In some embodiments, the aspect ratio of openings 204 is not less than 20 (i.e., for a 400 μm thickness TG, opening widths w1 of not more than 20 μm). Other aspect ratio via metallizations may be used. It is noted that the discussed dimensions of openings 204 substantially carry over to the resultant via metallizations formed within openings 204 and the via metallizations discussed herein below may have of the same dimensions, shapes, and characteristics.

FIG. 3 is an illustration of a cross-sectional side view of a glass substrate structure 300 similar to glass substrate structure 200 after deposition of a conformal sacrificial material layer 301 on first surface 202, second surface 203, and sidewalls 205 of openings 204 of glass substrate 201. Conformal sacrificial material layer 301 may be formed using any suitable technique or techniques such as spin coating a polymer mixed in a solvent solution. For example, the thickness of conformal sacrificial material layer 301 may be controlled using rotation speed and slurry viscosity during coating. Other example conformal coating techniques include liquid dispense, inkjet, dip coating, slit coating, squeegee-like coating, vacuum assisted plugging, and chemical vapor deposition (CVD).

Conformal sacrificial material layer 301 may be any suitable material that provides support for subsequent formation of via metallization that may be removed from between the via metallization and the sidewall of the glass substrate. In some embodiments, conformal sacrificial material layer 301 is polypropylene carbonate (PPC). In the context of the current flow, conformal sacrificial material layer 301 is removed through an overlying material layer (discussed below) and polypropylene carbonate may advantageously be decomposed and diffused through the material layer. Other example materials for conformal sacrificial material layer 301 include polyalkylcarbonates, cyclic poly (pthalaldehyde) [cPPA], polynorborene, polyaldehydes, poly(bisphenol carbonate), poly(resorcinol carbonate), poly(hydroquinone carbonate), and others.

Conformal sacrificial material layer 301 may have any suitable thickness (i.e., orthogonal to any surface of glass substrate 201). In some embodiments, conformal sacrificial material layer 301 has a thickness of not less than 5 nm and not more than 10 μm. In the context of the present flow, conformal sacrificial material layer 301 may advantageously have a thickness of not less than 5 nm and not more than 100 nm, a thickness of not less than 5 nm and not more than 50 nm, or a thickness of not less than 5 nm and not more than 20 nm. Other thicknesses may be used.

FIG. 4 is an illustration of a cross-sectional side view of a glass substrate structure 400 similar to glass substrate structure 300 after formation of a conformal seed metal layer 401 on conformal sacrificial material layer 301. Conformal seed metal layer 401 may be formed using any suitable technique or techniques such as sputter coating or electroless plating techniques or the like. Conformal seed metal layer 401 may be any suitable material for the subsequent growth of bulk metal material from conformal seed metal layer 401. In some embodiments, conformal seed metal layer 401 is a layer of titanium. Conformal seed metal layer 401 may have any suitable thickness (i.e., orthogonal to any surface of glass substrate 201) such as a thickness of about 100 to 200 nm.

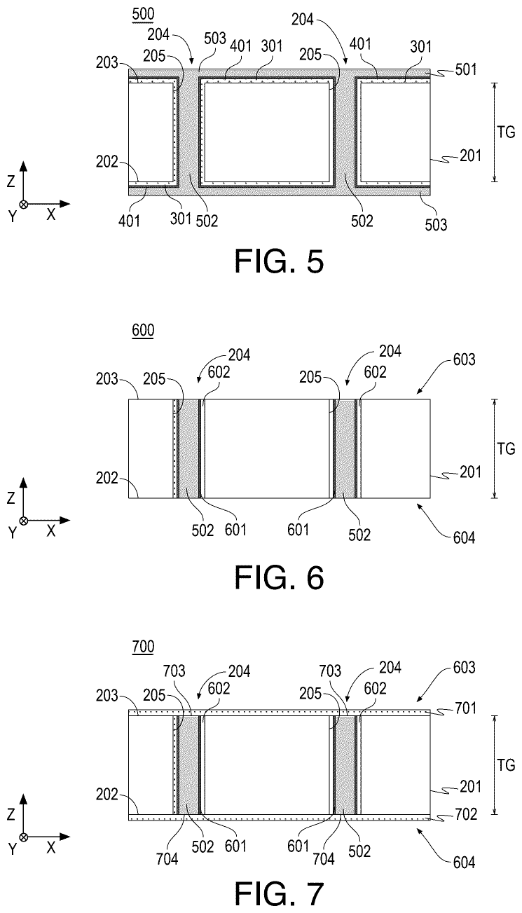

FIG. 5 is an illustration of a cross-sectional side view of a glass substrate structure 500 similar to glass substrate structure 400 after formation of a bulk metal 501 from conformal seed metal layer 401. Bulk metal 501 may be formed using any suitable technique or techniques such as electrolytic plating. In some embodiments, bulk metal 501 is copper such as substantially pure copper or pure copper. However, other material systems may be used. Bulk metal 501 includes overburdens 501, 503, and via metallizations 502.

FIG. 6 is an illustration of a cross-sectional side view of a glass substrate structure 600 similar to glass substrate structure 500 after planarization processing to remove overburdens 501, 503 and portions of conformal seed metal layer 401 and conformal sacrificial material layer 301 to form via metallization 502, sacrificial material layers 602, and metal seed layers 601. As shown, openings 204 are filled with via metallizations 502, sacrificial material layers 602, and metal seed layers 601. Exposed surfaces of via metallization 502, sacrificial material layers 602, and metal seed layers 601, along with first surface 202 and second surface 203, provide coplanar surfaces 603, 604. Together, via metallization 502 and metal seed layer 601 may be characterized as a via metallization within opening 204.

FIG. 7 is an illustration of a cross-sectional side view of a glass substrate structure 700 similar to glass substrate structure 600 after fabrication of material layers 701, 702 on coplanar surfaces 603, 604, respectively. As shown, material layers 701, 702 includes portions 703, 704 on via metallization 502 and metal seed layers 601, and extending over sacrificial material layers 602. Material layers 701, 702 may be any suitable material that allows for subsequent removal of sacrificial material layers 602 by diffusion through material layers 701, 702. In some embodiments, material layers 701, 702 are polymeric materials or organic dielectric materials such as an epoxy material, a polyimide material, a benzocyclobutene based material, a polyethylene terephthalate-based material, a high-density polyethylene material, or a polyethylene based material. In some embodiments, material layers 701, 702 is or includes a phenolic-glass, or a resinous film such as the GX-series films commercially available from Ajinomoto Fine-Techno Co., Inc. (ABF). Exemplary epoxy resins include an acrylate of novolac such as epoxy phenol novolacs (EPN) or epoxy cresol novolacs (ECN).

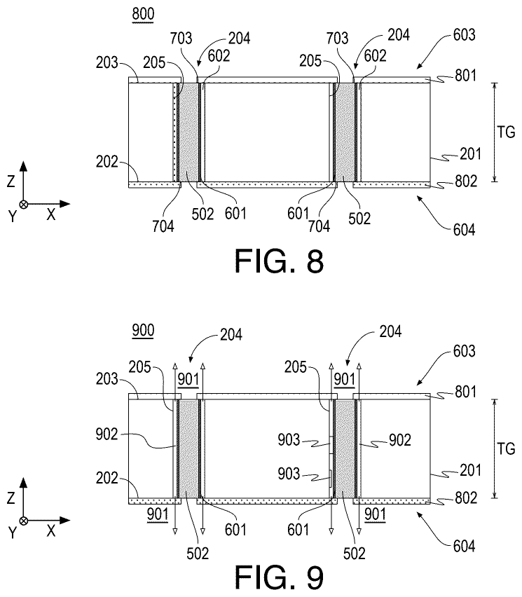

FIG. 8 is an illustration of a cross-sectional side view of a glass substrate structure 800 similar to glass substrate structure 700 after patterning material layers 701, 702 to expose portions of via metallization 502. And form patterned material layers 801, 802 Notably, after patterning, portions 703, 704 may remain on a portion of via metallization 502, on metal seed layers 601, and extend over sacrificial material layers 602. Glass substrate structures 700, 800 may be formed using any suitable technique or techniques. In some embodiments, a temporary carrier is attached over first surface 202, and second surface 203 is laminated with material layer 701 and material layer 701 is patterned to form patterned material layer 801. In some embodiments, a metal interconnect layer may also be formed during the mounting to the temporary carrier. For example, metallization 1001 (see FIG. 10) may be formed during such processing. Similarly, another temporary carrier is attached over second surface 203, the back-side temporary carrier is removed, and first surface 202 is processed in the same manner to form patterned material layer 802 and optional metallization 1002 (see FIG. 10). The second carrier may then be removed. Alternatively, the workpiece may be processed without carrier processing.

FIG. 9 is an illustration of a cross-sectional side view of a glass substrate structure 900 similar to glass substrate structure 800 after and during removal of sacrificial material layers 602 to form gaps 902. As shown, in some embodiments, residuals 903 may remain after removal processing 901. Sacrificial material layers 602 may be removed using any suitable technique or techniques such that removal processing 901 removes sacrificial material layers 602 through portions 703, 704 of patterned material layers 801, 802. Portions 703, 704 of patterned material layers 801, 802 may enclose gaps 902. In some embodiments, glass substrate structure 900 is placed inside a furnace at or about 250° C. in a vacuum environment to decompose sacrificial material layers 602 (e.g., PPC) into volatile products. The decomposed products may diffuse through patterned material layers 801, 802, which leaves gaps 902. Gaps 902 may be characterized as cavities, hollow cavities, air gaps, or the like. In some embodiments, residuals 903 remain. In some embodiments, substantially no residual is evident in gaps 902. Patterned material layers 801, 802 may be characterized as polymeric layers, material layers, polymer layers, buildup layers, or the like. As used herein the terms polymeric layers and polymer layers are used interchangeably to indicate a layer that is predominantly polymer material.

FIG. 10 is an illustration of a cross-sectional side view of a glass substrate structure 1000 similar to glass substrate structure 900 after removal of sacrificial material layers 602 to form gaps 902, and after formation of metallizations 1001, 1002 on opposing ends of via metallization 502. Metallizations 1001, 1002 may be formed using any suitable technique or techniques such as plating and planarization techniques. As discussed, in some embodiments, metallizations 1001, 1002 are fabricated while the workpiece is mounted to a carrier for formation of patterned material layers 801, 802.

As shown, glass substrate structure 1000 includes glass substrate 201 having thickness TG extending between first surface 202 and opposing second surface 203. Opening 204 extends from first surface 202 through thickness TG to second surface 203, and opening 204 defines sidewall 205. Via metallization 502 (inclusive of metal seed layer 601) is within opening 204 and extends from first surface 202 through thickness TG to second surface 203, and gap 902 is between via metallization 502 and sidewall 205. As shown in enlarged view 1021, gap 902 is between at least a region 1023 of via metallization 502 and a region 1022 of sidewall 205 within opening 204.

Gap 902 may have any suitable distance DG (distance gap) between via metallization 502 and sidewall 205. In some embodiments, the distance DG is not less than 5 nm and not more than 10 μm. In some embodiments, the distance DG is not less than 10 nm and not more than 1 μm. In some embodiments, the distance DAG is not less than 20 nm and not more than 500 nm. In some embodiments, the distance DAG is not less than 500 nm and not more than 2 μm. In some embodiments, the distance DAG is not less than 1 μm. Other distances may be used.

Furthermore, gaps 902 may be distributed in any manner through openings. As shown in enlarged view 1031, portions of via metallizations 502 are directly on (i.e., in physical contact with) regions 1032 of sidewalls 205 at some positions within opening 204. Furthermore, in some embodiments, residual 903 is directly on a region 1042 of sidewall 205 and/or directly on a region 1043 of via metallization 502. For example, residual 903 may include a polypropylene carbonate material or material layer. In some embodiments, the percentage of gap 902 area to total area within openings 204 is not less than 50%. In some embodiments, the percentage of gap 902 area to total area within openings 204 is not less than 75%. Other gap fractions may be used.

As shown in enlarged view 1011 taken at cross-section A-A′, via metallizations 502 (inclusive of metal seed layer 601) may be surrounded by gaps 902 either fully (as shown) or in part. Furthermore, opening 204 of glass substrate 201 defines an inner cross-sectional shape 1016. Inner cross-sectional shape 1016 may be any suitable shape such as circular (as shown), oval, or the like. As shown inner cross-sectional shape 1016 also substantially defines the cross-sectional shape of via metallizations 502 (inclusive of metal seed layer 601).

Discussion now turns to methods 100 for forming glass substrate structures with air gaps between a through glass via metallization and a sidewall of an opening in the glass substrate by removing an exposed sacrificial layer and optional subsequent backfill of a dielectric material.

FIG. 11 is an illustration of a cross-sectional side view of a glass substrate structure 1100 including materials received for processing at operation 101 such as glass substrate 201 having first surface 202, opposing second surface 203, and thickness TG extending between first surface 202 and second surface 203. In the context of FIGS. 11-21, glass substrate 201 is illustrated having a dual taper profile 1101 indicative of etching from both first surface 202 and second surface 203 after during laser assisted etch processing. However, in any processing context, openings 204 of glass substrate 201 may have dual taper profile 1101, a substantially constant cross-sectional profile (see FIG. 2), or a single taper profile (not shown), as the embodiments are not limited in this regard. Glass substrate 201 may have any characteristics discussed with respect to FIG. 2 herein.

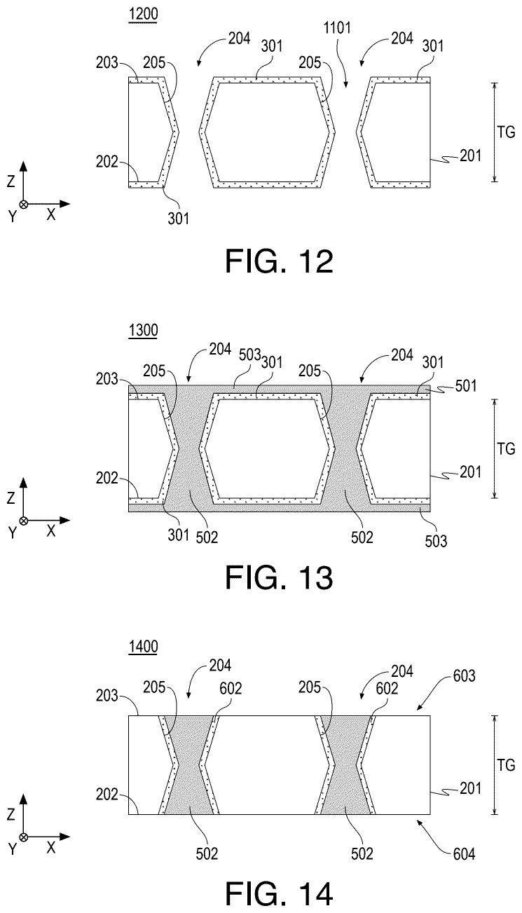

FIG. 12 is an illustration of a cross-sectional side view of a glass substrate structure 1200 similar to glass substrate structure 1200 after deposition of conformal sacrificial material layer 301 on first surface 202, second surface 203, and sidewalls 205 of openings 204 of glass substrate 201. Conformal sacrificial material layer 301 may be formed using any suitable technique or techniques such as those discussed with respect to FIG. 3. Furthermore, conformal sacrificial material layer 301 may be any suitable material that provides support for subsequent formation of via metallization that may be removed from between the via metallization and the sidewall of the glass substrate. Conformal sacrificial material layer 301 may be any material discussed herein above with respect to FIG. 3 such as polypropylene carbonate (PPC), polyalkylcarbonates, cyclic poly (pthalaldehyde) [cPPA], polynorborene, polyaldehydes, poly(bisphenol carbonate), poly(resorcinol carbonate), poly(hydroquinone carbonate), and others. In the context of the current flow, conformal sacrificial material layer 301 may be physically accessed during removal and, therefore, conformal sacrificial material layer 301 may be removed by thermal decomposition or solvent dissolution. In some embodiments, conformal sacrificial material layer 301 cyclic poly (pthalaldehyde) [cPPA], which offers advantages for formation of subsequent via metallizations and ease of removal. Conformal sacrificial material layer 301 may have any suitable thickness (i.e., orthogonal to any surface of glass substrate 201) as discussed herein with respect to FIG. 3.

FIG. 13 is an illustration of a cross-sectional side view of a glass substrate structure 1300 similar to glass substrate structure 1200 after formation of bulk metal 501. In some embodiments, glass substrate structure 1300 includes a conformal seed metal as discussed with respect to FIG. 4. For example, a seed metal layer 401 may be formed on conformal sacrificial material layer 301 (e.g., a titanium seed) using sputter coating techniques or electroless plating techniques, and bulk metal 501 (e.g., copper) may be plated from the seed metal layer 401. As shown, bulk metal 501 includes overburdens 501, 503, and via metallizations 502.

FIG. 14 is an illustration of a cross-sectional side view of a glass substrate structure 1400 similar to glass substrate structure 1300 after planarization processing to remove overburdens 501, 503 and portions of a conformal seed metal layer (if deployed) and conformal sacrificial material layer 301 to form via metallizations 502 and sacrificial material layers 602. As discussed, via metallizations 502 may include a metal seed layer. Openings 204 are filled with via metallization 502 and sacrificial material layers 602, and metal seed layers 601. Exposed surfaces of via metallization 502, sacrificial material layers 602, and metal seed layers 601, along with first surface 202 and second surface 203, provide coplanar surfaces 603, 604. Notably, regions of sacrificial material layers 602 are exposed in the context of glass substrate structure 1400.

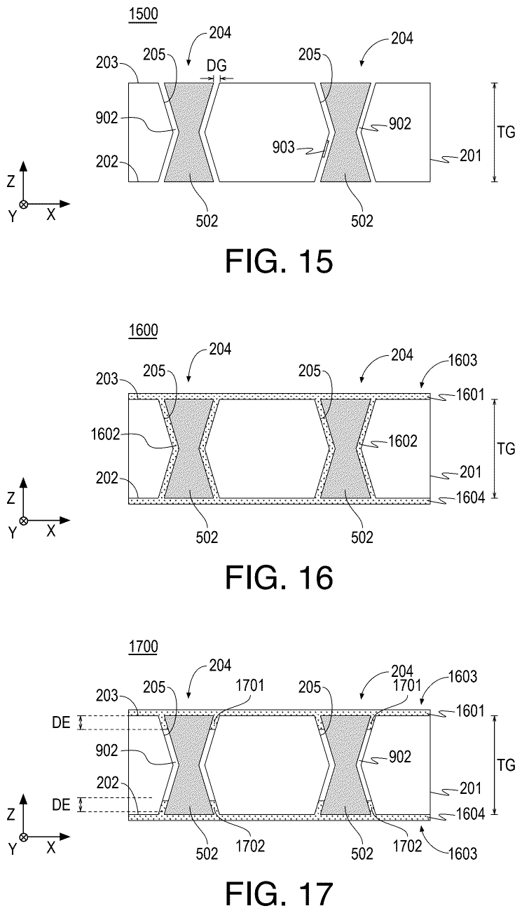

FIG. 15 is an illustration of a cross-sectional side view of a glass substrate structure 1500 similar to glass substrate structure 1400 after removal of sacrificial material layers 602 to form gaps 902. As shown, in some embodiments, residuals 903 may remain after removal processing. Sacrificial material layers 602 may be removed using any suitable technique or techniques. In the context of glass substrate structures 1400, 1500, sacrificial material layers 602 are accessible and, therefore, may be removed using a thermolytic decomposition process or a solvent dissolution process, depending on the material used for sacrificial material layers 602. In some embodiments, a thermal process may be done in parallel with a nominal metal annealing process, which may stabilize a grain structure of via metallizations 502 (e.g., copper plated via metallizations 502). For example, a high temperature anneal (e.g., 200° C. to 500° C.) can anneal via metallizations 502 and simultaneously decompose sacrificial material layers 602. Alternatively, sacrificial material layers 602 may be removed using a solvent that accesses sacrificial material layers 602 via one or both of first surface 202 and second surface 203. Gap 902 may have any suitable distance DG (distance gap) between via metallization 502 and sidewall 205 discussed herein above.

As discussed, removal of sacrificial material layers 602 advantageously decouples via metallizations 502 from sidewall 205 to reduce or mitigate stresses on glass substrate. In some embodiments, gaps 902 may be fully or partially backfilled with a pliant material for improved securement of via metallizations 502 within openings and/or for additional stress reduction. In some embodiments, at the point of backfill processing, via metallizations 502 may have already undergone high temperature annealing/thermal processing and the corresponding plastic deformation as a result thereof, and via metallizations 502 may produce lesser stresses in subsequent thermal cycles, if any.

FIG. 16 is an illustration of a cross-sectional side view of a glass substrate structure 1600 similar to glass substrate structure 1500 after backfilling gaps 902 with fill material 1603, which includes first surface cover portion 1604, second surface cover portion 1601, and gap fill portions 1602. In the context of glass substrate structure 1600, gap fill portions 1602 fully backfill gaps 902 and such processing is from both first surface 202 and second surface 203.

Fill material 1603, including first surface cover portion 1604, second surface cover portion 1601, and gap fill portions 1602 may be formed using any suitable technique or techniques such as deposition under vacuum. In some embodiments, fill material 1603 is a polymeric material or organic dielectric material such as an epoxy material, a polyimide material, a benzocyclobutene based material, a polyethylene terephthalate-based material, a high-density polyethylene material, or a polyethylene-based material. Glass substrate structure 1600 may continue with processing to expose surfaces of via metallizations 502 adjacent first surface 202 and second surface 203 and incorporation of the glass substrate structure into a package structure, as discussed with respect to FIGS. 29-31.

FIG. 17 is an illustration of a cross-sectional side view of a glass substrate structure 1700 similar to glass substrate structure 1600 after partially backfilling gaps 902 with fill material 1603, which includes first surface cover portion 1604, second surface cover portion 1601, and gap fill extensions 1701, 1702. In the context of glass substrate structure 1700, gap fill extensions 1701, 1702 partially backfill gaps 902 and such processing is from both first surface 202 and second surface 203. As discussed with respect to FIG. 16, fill material 1603 may be formed using any suitable technique or techniques such as deposition under vacuum, and fill material 1603 may be a polymeric material or organic dielectric material.

As shown, gap fill extensions 1701, 1702 extend a particular distance DE (distance of extension). The distance LE of gap fill extensions 1701, 1702 is along sidewall 205 of opening 204 and may be any suitable distance. In some embodiments, distance DE of gap fill extensions 1701, 1702 is not less than 5 μm and not more than 20 μm. In some embodiments, distance DE of gap fill extensions 1701, 1702 is not less than 10 μm and not more than 15 μm. In some embodiments, distance DE of gap fill extensions 1701, 1702 is not less than 5 μm and not more than 8 μm. In some embodiments, distance DE of gap fill extensions 1701, 1702 is not less than 10 μm. In some embodiments, distance DE of gap fill extensions 1701, 1702 is a particular fraction of thickness TG of glass substrate 201. In some embodiments, distance DE of gap fill extensions 1701, 1702 is not less than 5% of thickness TG of glass substrate 201. In some embodiments, distance DE of gap fill extensions 1701, 1702 is not less than 10% of thickness TG of glass substrate 201. In some embodiments, distance DE of gap fill extensions 1701, 1702 is not less than 20% of thickness TG of glass substrate 201. Other distance DE may be used.

In the context of partial backfill as shown with respect to FIG. 17 and FIG. 21 below, fill material 1603 provides a sealing around via metallization 502 at first surface 202 and bottom surface 203, which advantageously provides for a bulk of opening 204 to be gap 902 (e.g., an air gap) that provides the ultra-low Df/Dk of air (or low pressure air to vacuum if vacuum lamination processes are used for the backfilling). Glass substrate structure 1700 may continue with processing to expose surfaces of via metallizations 502 adjacent first surface 202 and second surface 203 and incorporation of the glass substrate structure into a package structure, as discussed with respect to FIGS. 29-31.

As discussed, sacrificial material layers 602 may be removed and fill material 1603 may be formed from first surface 202 and second surface 203 simultaneously. Alternatively, single-sided processing may be used to remove sacrificial material layers 602 and to provide fill material 1603. Such techniques may offer the advantages of increased structural support for glass substrate 201 and/or immediate access to exposed via metallizations, for example.

FIG. 18 is an illustration of a cross-sectional side view of a glass substrate structure 1800 similar to glass substrate structure 1400 after attachment of glass substrate 201 to a handle or carrier 1801. Carrier 1801 may have any suitable composition and may be of any suitable thickness. Glass substrate 201 may be attached to carrier 1801 using any suitable technique or techniques such as a removable adhesive, a releasable tape, or the like.

FIG. 19 is an illustration of a cross-sectional side view of a glass substrate structure 1900 similar to glass substrate structure 1800 after removal of sacrificial material layers 602 to form gaps 902. Sacrificial material layers 602 may be removed using any suitable technique or techniques discussed above such as thermolytic decomposition process or solvent dissolution process, depending on the material of sacrificial material layers 602. Notably, in the context of FIG. 19, sacrificial material layers 602 is removed using single-sided processing by accessing sacrificial material layers 602 at second surface 203.

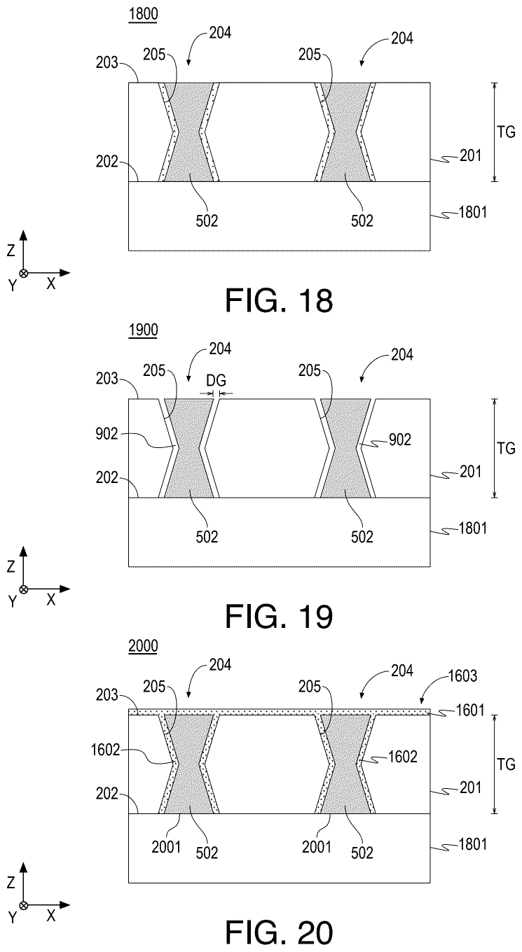

FIG. 20 is an illustration of a cross-sectional side view of a glass substrate structure 2000 similar to glass substrate structure 1900 after fully backfilling gaps 902 with fill material 1603, which, in the context of glass substrate structure 2000, includes second surface cover portion 1601 and gap fill portions 1602 (and is absent first surface cover portion 1604). Gap fill portions 1602 fully backfill gaps 902 and such processing is only from second surface 203, leaving surfaces 2001 exposed (after removal of carrier 1801) for additional processing. Fill material 1603 may be formed by deposition under vacuum and fill material 1603 may be a polymeric material or organic dielectric material, as discussed. Glass substrate structure 2000 may continue with processing to remove carrier 1801, and to expose surfaces of via metallizations 502 adjacent second surface 203 and incorporation of the glass substrate structure into a package structure, as discussed with respect to FIGS. 29-31.

FIG. 21 is an illustration of a cross-sectional side view of a glass substrate structure 2100 similar to glass substrate structure 1900 after partially backfilling gaps 902 with fill material 1603, which includes second surface cover portion 1601 and gap fill extensions 1701, and after removal of carrier 1801. In the context of glass substrate structure 2100, gap fill extensions 1701 partially backfill gaps 902 from only second surface 203. Fill material 1603 may be formed using any suitable technique or techniques such as deposition under vacuum in the presence of carrier 1801, and fill material 1603 may be a polymeric material or organic dielectric material.

Gap fill extensions 1701 extend distance DE into gaps 902 from second surface 203 while gaps 902 adjacent first surface 202 have openings 2101 adjacent exposed surfaces 2001 of via metallizations 502. The distance DE of gap fill extensions 1701 may be any distance DE discussed above. Glass substrate structure 2100 may continue with processing to expose surfaces of via metallizations 502 adjacent second surface 203 and incorporation of the glass substrate structure into a package structure, as discussed with respect to FIGS. 29-31.

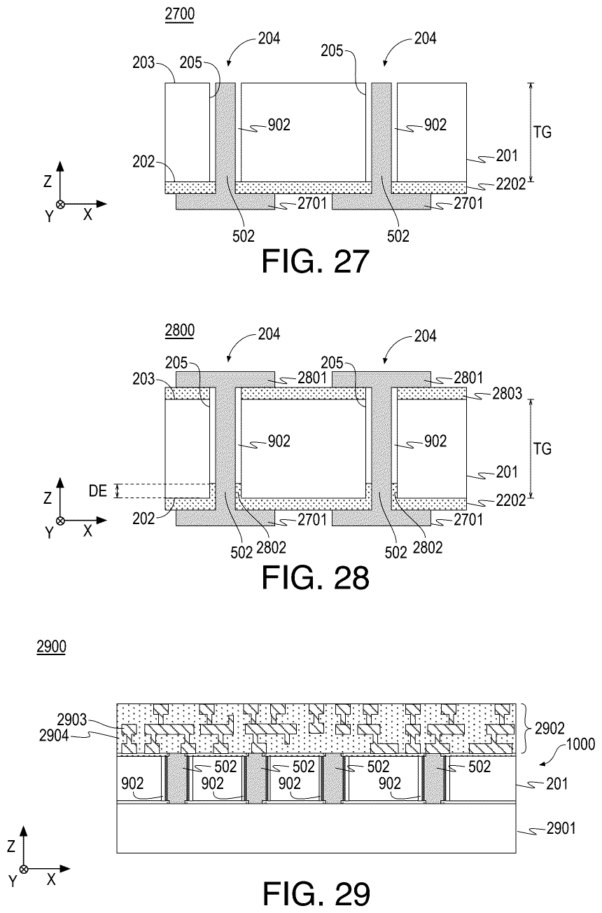

It is noted that the full backfill and partial backfill operations discussed with respect to FIGS. 16-21 may be performed with respect to any exposed gaps discussed herein such as those illustrated with respect to FIGS. 26 and 27 in the context of bottom-up plating of via metallizations.

Discussion now turns to methods 100 for forming glass substrate structures with air gaps between a through glass via metallization and a sidewall of an opening in the glass substrate by removing a sacrificial layer from a bottom-up filled via metallization.

FIG. 22 is an illustration of a cross-sectional side view of a glass substrate structure 2200 similar to glass substrate structure 200 after attachment of a material layer 2202 that substantially covers first surface 202 and seals one side of each of openings 204 at first surface 202, and attachment of a metal layer 2201 to material layer 2202. Material layer 2202 may be any material that covers first surface 202 and openings 204 and provides an etch selectivity with respect to metal seed layer 2201. For example, subsequent etch processing may be directional and selectively remove material layer 2202 from a portion of metal layer 2201 such that he exposed portion of metal layer 2201 within opening 204 provides a seed for subsequent bottom-up plating.

In some embodiments, material layer 2202 is one of an epoxy material, a polyimide material, a benzocyclobutene based material, a polyethylene terephthalate-based material, a high-density polyethylene material or a polyethylene-based material. In some embodiments, material layer 2202 is a build-up film such as Ajinomoto build-up film (ABF). Material layer 2202 or portions thereof may remain in the resultant package formed using glass substrate 201 to provide additional adhesion properties for the resultant via metallization or other components and/or improved insulation. Material layer 2202 may be attached to first surface using lamination techniques or coating techniques. Metal layer 2201 may be any suitable material or materials that provide a seed for plating subsequent via metallizations. In some embodiments, metal layer 2201 is copper layer. In some embodiments, metal layer 2201 is formed using deposition techniques such as plating techniques. In some embodiments, metal layer 2201 is applied as a metal foil such as a copper foil. In some embodiments, portions of metal layer 2201 (after patterning) are used as metallization pads for contacting metal vias and for signal, power, or ground routing. For example, portions of metal layer 2201 may be part of a redistribution layer or structure for a resultant package structure.

FIG. 23 is an illustration of a cross-sectional side view of a glass substrate structure 2300 similar to glass substrate structure 2200 after deposition of a conformal sacrificial layer 2301 on second surface 203, sidewalls 205, and a portion 2302 of material layer 2202. Conformal sacrificial layer 2301 may be deposited using any suitable technique or techniques such as CVD, PVD, ALD, or the like. Conformal sacrificial layer 2301 may be any material discussed herein above with respect to sacrificial material layer 301.

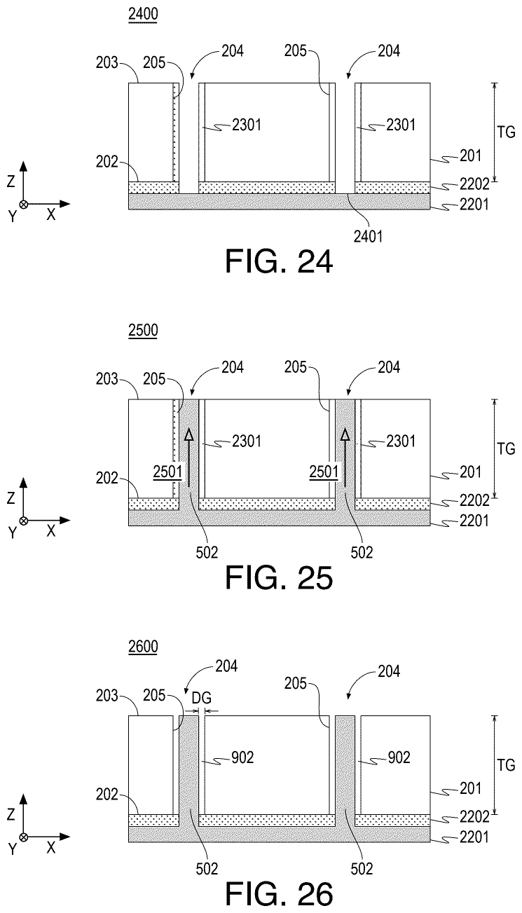

FIG. 24 is an illustration of a cross-sectional side view of a glass substrate structure 2400 similar to glass substrate structure 2300 after directional selective etch of conformal sacrificial layer 2301 and portion 2302 of material layer 2202 to expose a region or portion 2401 of metal seed layer 2201. The directional selective etch of conformal sacrificial layer 2301 and portion 2302 of material layer 2202 may be performed using any suitable technique or techniques. In some embodiments, the directional selective etch is a selective vertical sputter etch. As shown, the etch is vertically directional (i.e., in the negative z-direction) and selective, stopping on metal layer 2201 as well as second surface 203 of glass substrate 201. Notably, the directional selective etch exposes portion 2401 of metal layer 2201 for use as a seed in bottom-up plating.

FIG. 25 is an illustration of a cross-sectional side view of a glass substrate structure 2500 similar to glass substrate structure 2400 after bottom-up plating 2501 of via metallizations 502 within openings 204, and after optional removal of any overburden formed by bottom-up plating 2501. Bottom-up plating 2501 progresses up from metal layer 2201 to fill openings 204 with via metallization 502. Via metallization 502 may be any suitable material such as substantially pure or pure copper. After bottom-up plating 2501, any overburden may be removed using planarization, for example, such that via metallizations 502 remain only adjacent to sidewalls 205 of openings 204.

Notably, via metallizations 502 formed within openings 204 using bottom-up plating 2501 are absent a seed layer adjacent sidewall 205. A seed layer, as discussed, can be a different material than the bulk (e.g., a titanium or titanium-copper seed layer for a bulk copper) or a different microstructure (e.g., a seed layer having a different grain size than the bulk metal). In some embodiments, an entirety of via metallizations 502 are a substantially pure (99%+) or pure (99.9%+) metal such as substantially pure or pure copper having a constant microstructure throughout. As used herein, the term microstructure indicates the microscopic structure of the material and refers to the arrangement of the materials constituents such as grains, defects, grain boundaries, etc. The term constant throughout is used to indicate each portion of the material has the same or similar microstructure in each of the regions.

FIG. 26 is an illustration of a cross-sectional side view of a glass substrate structure 2600 similar to glass substrate structure 2500 after removal of conformal sacrificial layers 2301 to form gaps 902. As discussed, in some embodiments, residuals 903 may remain after removal processing (see FIGS. 9 & 15). In the context of glass substrate structures 2500, 2600, conformal sacrificial layers 2301 are accessible and, therefore, may be removed using a thermolytic decomposition process or a solvent dissolution process, depending on the material deployed. In some embodiments, a thermal process may be done in parallel with a nominal metal annealing process, as discussed above. Alternatively, conformal sacrificial layers 2301 may be removed using a solvent that accesses conformal sacrificial layers 2301 via second surface 203. Gap 902 may have any suitable distance DG (distance gap) between via metallization 502 and sidewall 205 discussed herein above. Removal of conformal sacrificial layers 2301 advantageously decouples via metallizations 502 from sidewall 205 to reduce or mitigate stresses on glass substrate.

FIG. 27 is an illustration of a cross-sectional side view of a glass substrate structure 2700 similar to glass substrate structure 2600 after patterning metal layer 2201 to form metal routes or pads 2701. Metal layer 2201 may be patterned using any suitable technique or techniques such as subtractive etch techniques. Metal pads 2701 may provide for landing structures to couple to via metallizations 502, and metal pads 2701 may be part of a metallization structure, redistribution structure, or the like.

With reference to FIG. 22, material layer 2202 may be formed on first surface 202. Although illustrated as being formed on a back-side of glass substrate 201, material layer 2202 may be formed on first surface 202 in a downward direction such that portions of material layer 2202 are formed on sidewalls 205. In such contexts, material layer extensions, similar to gap fill extensions 1701, 1702 may be formed in openings 204.

FIG. 28 is an illustration of a cross-sectional side view of a glass substrate structure 2800 similar to glass substrate structure 2700 where material layer extensions 2802 are formed in openings 204, and where a material layer 2803 and metal pads 2801 are formed over second surface 203. Material layer extensions 2802 may be any materials discussed with respect to material layer 2202, and material layer extensions 2802 extend into openings by a distance DE such that material layer extensions 2802 are between a region of via metallization 502 and a region of sidewall 205. Material layer extensions 2802 may provide a seal around via metallization 502 at first surface 202 which secures via metallization 502 with opening 204 during processing and subsequent implement in a package structure. The distance DE of material layer extensions 2802 may be any distance DE discussed with respect to gap fill extensions 1701, 1702.

Also as shown in FIG. 28, material layer 2803 and metal pads 2801 may be formed over second surface 203. Material layer 2803 may be any material that covers second surface 203 such as an epoxy material, a polyimide material, a benzocyclobutene based material, a polyethylene terephthalate-based material, a high-density polyethylene material or a polyethylene-based material. In some embodiments, material layer 2803 is a build-up film such as Ajinomoto build-up film (ABF). In some embodiments, material layer 2803 includes material layer extensions similar to material layer extensions 2802. Material layer 2803 may be formed using any suitable technique or techniques such as deposition and patterning techniques. Metal pads 2801 may be formed by deposition of a metal layer followed by subtractive patterning, for example. Metal pads 2801 may use any material system and, in some embodiments metal pads 2801 are substantially pure or pure copper. Metal pads 2801 may provide for landing structures to couple to via metallizations 902, and metal pads 2801 may be part of a metallization structure, redistribution structure, or the like.

As shown, glass substrate structure 2800 includes glass substrate 201 having thickness TG extending between first surface 202 and opposing second surface 203. Opening 204 extends from first surface 202 through thickness TG to second surface 203, and opening 204 defines sidewall 205. Via metallization 502 (i.e., a bottom-up plated via) is within opening 204 and extends from first surface 202 through thickness TG to second surface 203, and gap 902 is between via metallization 502 and sidewall 205, such that gap 902 is between at least a region of via metallization 502 and a region of sidewall 205 within opening 204. Furthermore, glass substrate structure 2800 includes material layer 2202, such as a polymeric material or organic material, having a first portion on first surface 202 and material layer extensions 2802 extending into opening 204 adjacent first surface 202 such that gap 902 is immediately adjacent material layer extensions 2802 within opening 204. Glass substrate structure 2800 further includes metal pad 2701 on material layer 2202 and metal pad 2801 over second surface 203 and coupled to via metallization 502 such gap 902 extends from material layer extensions 2802 to metal pad 2801.

Returning to FIG. 1, methods 100 continue at operation 106, where an electrical routing structure may be built up over at least one side of the glass substrate prior to assembly with an integrated die. The electrical routing structure may be electrically coupled to the through glass vias and may, for example, include one or more levels of metallization features embedded within any suitable dielectric material. The electrical routing structure formed at operation 106 may interconnect one or more IC die to each other and/or couple one or more of IC die to the conductive through vias. Accordingly, the metallization feature pitch of the routing structure is advantageously minimized for highest interconnect density.

FIG. 29 is an illustration of a cross-sectional side view of a package structure 2900 similar to glass substrate structure 1000 after attachment of glass substrate structure 1000 to a handle or carrier 2901 and fabrication or attachment of routing structure 2902. Although illustrated with respect to incorporation of glass substrate structure 1000 into package structures 2900, 3000, 3100, any glass substrate structure discussed herein having any of the discussed characteristics may be deployed in package structures 2900, 3000, 3100. Carrier 2901 may have any suitable composition and may be of any suitable thickness. Furthermore, glass substrate structure 1000 may be attached to carrier 2901 using any suitable technique or techniques such as a removable adhesive, a releasable tape, or the like.

Although illustrated with respect to routing structure (or redistribution layer) formed over second surface 203, in some embodiments two-sided architectures include a redistribution layer over both first surface 202 and second surface 203. In some embodiments, routing structure 2902 is built-up over second surface 203. In other embodiments a routing structure is built-up over first surface 202 or a routing structure is built up over both first surface 202 and second surface 203. As shown, routing structure 2902 includes one or more levels of redistribution layer (RDL) metallization features 2903 embedded within one or more layers of dielectric material 2904. RDL metallization features 2903 may include any suitable metal such as copper. In some embodiments, a portion of RDL metallization features 2903 are to electrically bridge together two or more IC dies, preferably with a fine metallization feature pitch as enabled by the improved flatness profile of glass substrate 201 as compared to traditional organic preform cores. Furthermore, a portion of routing structure 2902 further includes metallization features 2903 that are to interconnect IC dies to via metallizations 502.

Dielectric material 2904 may be any suitable material or materials such as a molding compound, a spin-on material, or a dry film laminate material. In some embodiments, dielectric material 2904 is applied in a wet or uncured state into a cast and is then dried or cured. Alternatively, dielectric material 2904 may be applied as a semi-cured dry film that is fully cured following its application to glass substrate 201. The composition of dielectric material 2904 may include one or more of an organic dielectric material, such as, an epoxy resin, phenolic-glass, or a resinous film such as the GX-series films commercially available from Ajinomoto Fine-Techno Co., Inc. (ABF). Exemplary epoxy resins for deployment in dielectric material 2904 include an acrylate of novolac such as epoxy phenol novolacs (EPN) or epoxy cresol novolacs (ECN). In some embodiments, dielectric material 2904 is a bisphenol-A epoxy resin including epichlorohydrin, for example. In some embodiments, dielectric material 2904 includes an aliphatic epoxy resin.

Returning to FIG. 1, methods 100 continue at operation 107, where at least one IC die is assembled to the workpiece. In some embodiments, the one or more IC dies are attached to the electrical routing structure formed at operation 106. The one or more IC dies assembled at operation 107 may each include any electrical circuitry. In some embodiments, one or more of the IC dies include logic circuitry including logic gates. The one or more IC dies assembled at operation 107 may also include any photonic circuitry suitable for the detection, emission or processing (e.g., filtering, multiplexing and demultiplexing) of optical signals.

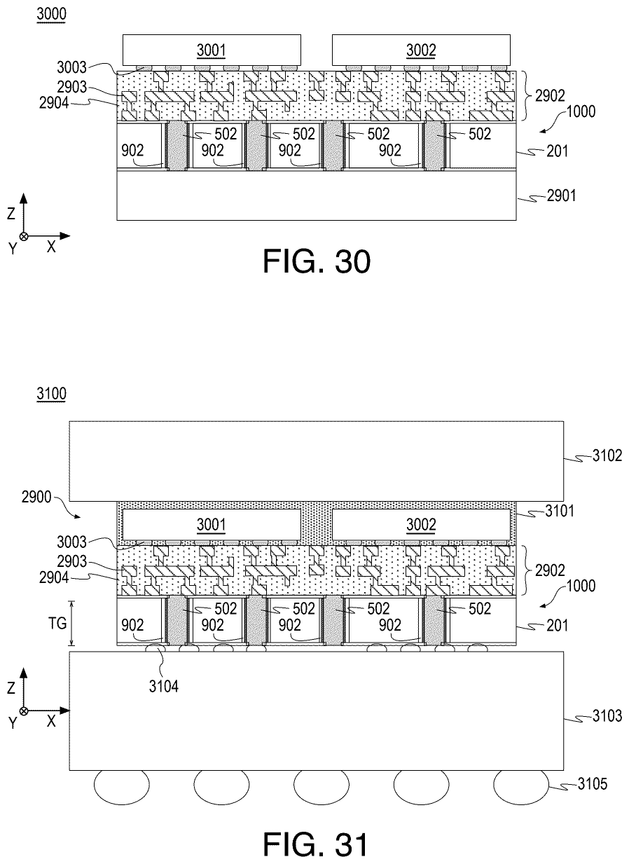

FIG. 30 is an illustration of a cross-sectional side view of a package structure 3000 similar to package structure 2900 after attachment of any number of IC dies such as IC dies 3001, 3002 to routing structure 2902 using intervening electrical interconnects 3003. As shown, IC dies 3001, 3002 are assembled to interconnect interfaces within a top metallization level of routing structure 2902 of an assembled package structure 3000. Although illustrated with two IC dies 3001, 3002, package structure 3000 may include any number of IC dies. In some embodiments, IC dies 3001, 3002 are the first level of dies of a packaged multi-die IC device package structure. IC dies 3001, 3002 may be directly bonded to routing structure 2902, or, electrically coupled through intervening electrical interconnects 3003, which may include solder of any suitable composition. In the example illustrated, IC dies 3001, 3002 are each flip-chip attached with integrated circuitry within each die being proximal to a top surface of routing structure 2902. In alternative embodiments, IC dies 3001, 3002 include through die vias (not shown) with integrated circuity being distal from the top surface of routing structure 2902.

IC dies 3001, 3002 may include any suitable circuitry. In some embodiments, at least one of IC dies 3001, 3002 is a fully functional ASIC. In some embodiments, IC dies 3001, 3002 include a chiplet or tile that has more limited functionality supplementing the function of one or more others of IC dies 3001, 3002 that are to be part of the same multi-die device. A chiplet or tile may, for example, be any of a wireless radio circuit, microprocessor core, electronic memory circuit, floating point gate array (FPGA), power management and/or power supply circuit, or a MEMS device. In some examples, one or more of IC dies 3001, 3002 includes one or more banks of active repeater circuitry to improve multi-die interconnects (e.g., network-on-chip architectures). In other examples, one or more of IC dies 3001, 3002 includes clock generator circuitry or temperature sensing circuitry. In other examples, one or more of IC dies 3001, 3002 includes logic circuitry that, along with other IC dies 3001, 3002 implement multi-chiplet aggregated logic circuitry (e.g., mesh network-on-chip architectures). In some specific examples, at least one of IC dies 3001, 3002 includes microprocessor core circuitry, for example including one or more shift registers. IC dies 3001, 3002 may include field effect transistors (FETs) with a device pitch of 80 nm, or less. The FETs may be of any architecture (e.g., planar, non-planar, single-gate, multi-gate, stacked nanosheet, etc.). Additionally or in the alternative, IC dies 3001, 3002 may include active devices other than FETs such as magnetic tunnel junctions (MTJs), capacitors, or the like. In some embodiments, IC dies 3001, 3002 include one or more IC die metallization levels embedded within an insulator.

Returning to FIG. 1, methods 100 continue at operation 108, where the final device is packaged, assembled, and output, for example, by attachment of a package to a host component. The assembly or package may be installed in any suitable electronic device such as a laptop, a netbook, a notebook, an ultrabook, a smartphone, a tablet, a personal digital assistant PDA, an ultra-mobile PC, a mobile phone, a desktop computer, a server, a printer, a scanner, a monitor, a set-top box, an entertainment control unit, a digital camera, a portable music player, a digital video recorder, or the like.

FIG. 31 is an illustration of a cross-sectional side view of a package structure 3100 similar to package structure 3000 after attachment to a host component 3103 and deployment of one or more heat spreaders and/or heat sinks 3102. As shown, package structure 3100, which may be characterized as a system, includes package structure 3000 attached to host component 3103 with interconnects 3104. In some embodiments, interconnects 3104 are solder (e.g., SAC) microbumps although other interconnect features may be used. In some embodiments, host component 3103 is predominantly silicon. Host component 3103 may also include one or more alternative materials known to be suitable as interposers or package substrates (e.g., an epoxy preform, cored or coreless laminate board, etc.). In some embodiments, host component 3103 is a printed circuit board (PCB). In some embodiments, host component 3103 includes one or more metallized redistribution levels (not depicted) embedded within a dielectric material. Host component 3103 may also include one or more IC dies, one or more passive or active components, or the like embedded therein.

Host component 3103 may include interconnects 3105 which may include solder (e.g., ball, bump, etc.) suitable for a given host board architecture (e.g., surface mount FR4, etc.). Also as shown, one or more heat spreaders and/or heat sinks 3102 may be coupled to package structure 3000, which may be advantageous, for example, where IC dies 3001, 3002 include one or more CPU cores or other circuitry of similar power density. Any package dielectric 3101, such as a mold material, may surround sidewalls of IC dies 3001, 3002. Although not illustrated, package dielectric 3101 may be ground down to a top surface of IC dies 3001, 3002 such that heat spreader/sink 3102 may be in closer contact with IC dies 3001, 3002.

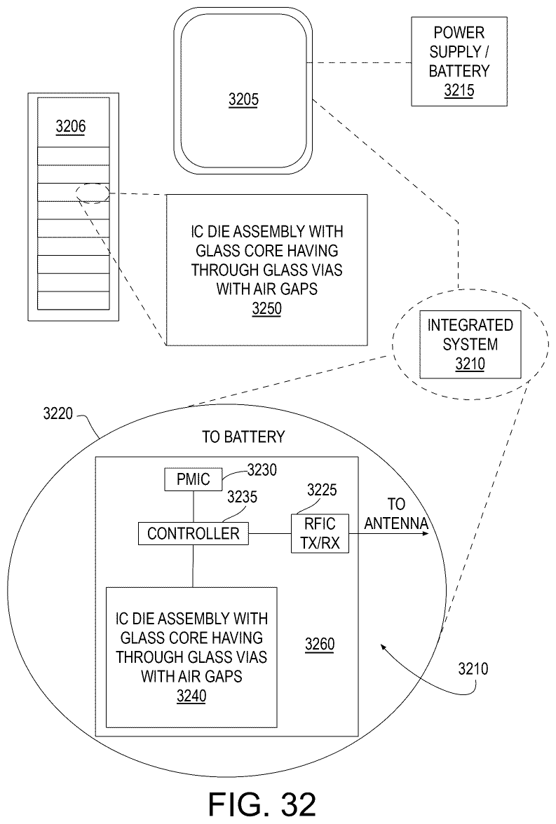

FIG. 32 illustrates exemplary systems employing an IC assembly including a glass core substrate with one or more air gaps between a through glass via metallization and a sidewall of an opening in the glass substrate, arranged in accordance with at least some implementations of the present disclosure. The system may be a mobile computing platform 3205 and/or a data server machine 3206, for example. Either may employ a component assembly including an IC assembly including a glass core substrate with one or more air gaps between a through glass via metallization and a sidewall of an opening in the glass substrate as described elsewhere herein. Server machine 3206 may be any commercial server, for example including any number of high-performance computing platforms disposed within a rack and networked together for electronic data processing, which in the exemplary embodiment includes an IC die assembly 3250 with a glass core substrate with one or more air gaps between a through glass via metallization and a sidewall of an opening in the glass substrate as described elsewhere herein. Mobile computing platform 3205 may be any portable device configured for each of electronic data display, electronic data processing, wireless electronic data transmission, or the like. For example, mobile computing platform 3205 may be any of a tablet, a smart phone, a laptop computer, etc., and may include a display screen (e.g., a capacitive, inductive, resistive, or optical touchscreen), a chip-level or package-level integrated system 3210, and a battery 3215 and/or power supply circuitry. Although illustrated with respect to mobile computing platform 3205, in other examples, chip-level or package-level integrated system 3210 and battery 3215 may be implemented in a desktop computing platform, an automotive computing platform, an internet of things platform, or the like. As discussed below, in some examples, the disclosed systems may include a sub-system 3260 such as a system on a chip (SOC) or an integrated system of multiple ICs, which is illustrated with respect to mobile computing platform 3205.

Whether disposed within integrated system 3210 illustrated in expanded view 3220 or as a stand-alone packaged device within data server machine 3206, sub-system 3260 may include memory circuitry and/or processor circuitry 3240 (e.g., RAM, a microprocessor, a multi-core microprocessor, graphics processor, etc.), a power management integrated circuit (PMIC) 3230, a controller 3235, and a radio frequency integrated circuit (RFIC) 3225 (e.g., including a wideband RF transmitter and/or receiver (TX/RX)). As shown, one or more IC dies, such as memory circuitry and/or processor circuitry 3240 may be assembled and implemented such that one or more have an IC assembly including a glass core substrate with one or more air gaps between a through glass via metallization and a sidewall of an opening in the glass substrate as described herein. In some embodiments, RFIC 3225 includes a digital baseband and an analog front-end module further including a power amplifier on a transmit path and a low noise amplifier on a receive path. Functionally, PMIC 3230 may perform battery power regulation, DC-to-DC conversion, etc., and so has an input coupled to battery 3215, and an output providing a current supply to other functional modules. As further illustrated in FIG. 32, in the exemplary embodiment, RFIC 3225 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 3240 may provide memory functionality for sub-system 3260, high level control, data processing and the like for sub-system 3260. In alternative implementations, each of the SOC modules may be integrated onto separate ICs coupled to a package substrate, interposer, or board.

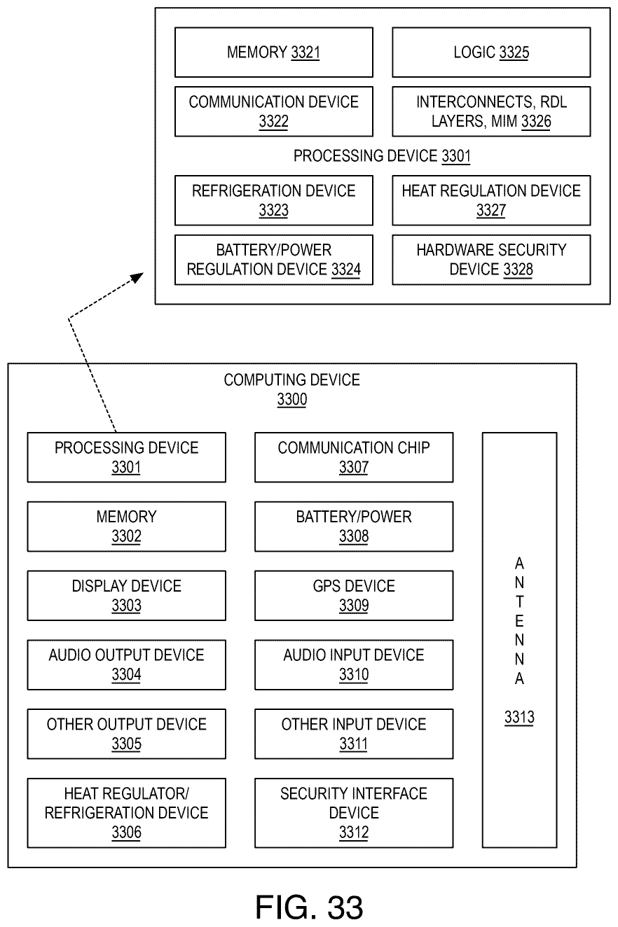

FIG. 33 is a block diagram of a computing device 3300, in accordance with some embodiments. For example, one or more components of computing device 3300 may include any of the package structures or assemblies having a glass core substrate with one or more air gaps between a through glass via metallization and a sidewall of an opening in the glass substrate as discussed elsewhere herein. A number of components are illustrated in FIG. 33, but any one or more of these components may be omitted or duplicated, as suitable for the application. In some embodiments, some of the components included in computing device 3300 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Any of such packaged components may include a glass core substrate with one or more air gaps, for example, as discussed herein. Additionally, in various embodiments, computing device 3300 may not include one or more of the components illustrated in FIG. 33, but computing device 3300 may include interface circuitry for coupling to the one or more components. For example, computing device 3300 may not include a display device 3303, but may include display device interface circuitry (e.g., a connector and driver circuitry) to which display device 3303 may be coupled.

Computing device 3300 may include a processing device 3301 (e.g., one or more processing devices). As used herein, the term processing device or processor indicates a device that processes electronic data from registers and/or memory to transform that electronic data into other electronic data that may be stored in registers and/or memory. Processing device 3301 may include a memory 3321, a communication device 3322, a refrigeration/active cooling device 3323, a battery/power regulation device 3324, logic 3325, interconnects 3326, a heat regulation device 3327, and a hardware security device 3328.

Processing device 3301 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable compute units.

Processing device 3301 may include a memory 3302, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 3301 shares a package with memory 3302. This memory may be used as cache memory and may include embedded dynamic random-access memory (eDRAM) or spin transfer torque magnetic random-access memory (STT-M RAM).

Computing device 3300 may include a heat regulation/refrigeration device 3306. Heat regulation/refrigeration device 3306 may maintain processing device 3301 (and/or other components of computing device 3300) at a predetermined low temperature during operation. This predetermined low temperature may be any temperature discussed elsewhere herein.

In some embodiments, computing device 3300 may include a communication chip 3307 (e.g., one or more communication chips). For example, the communication chip 3307 may be configured for managing wireless communications for the transfer of data to and from computing device 3300. The term “wireless” and its derivatives may be used to describe circuits, devices, systems, methods, techniques, communications channels, etc., that may communicate data through the use of modulated electromagnetic radiation through a nonsolid medium.

Computing device 3300 may include any photonics structure discussed herein that may facilitate communication between one or more instances of processing device 3301 and/or one or more instances of memory 3302, for example.

Computing device 3300 may include battery/power circuitry 3308. Battery/power circuitry 3308 may include one or more energy storage devices (e.g., batteries or capacitors) and/or circuitry for coupling components of computing device 3300 to an energy source separate from computing device 3300 (e.g., AC line power).

Computing device 3300 may include a display device 3303 (or corresponding interface circuitry, as discussed above). Display device 3303 may include any visual indicators, such as a heads-up display, a computer monitor, a projector, a touchscreen display, a liquid crystal display (LCD), a light-emitting diode display, or a flat panel display, for example.

Computing device 3300 may include an audio output device 3304 (or corresponding interface circuitry, as discussed above). Audio output device 3304 may include any device that generates an audible indicator, such as speakers, headsets, or earbuds, for example.

Computing device 3300 may include an audio input device 3310 (or corresponding interface circuitry, as discussed above). Audio input device 3310 may include any device that generates a signal representative of a sound, such as microphones, microphone arrays, or digital instruments (e.g., instruments having a musical instrument digital interface (MIDI) output).

Computing device 3300 may include a global positioning system (GPS) device 3309 (or corresponding interface circuitry, as discussed above). GPS device 3309 may be in communication with a satellite-based system and may receive a location of computing device 3300, as known in the art.

Computing device 3300 may include another output device 3305 (or corresponding interface circuitry, as discussed above). Examples include an audio codec, a video codec, a printer, a wired or wireless transmitter for providing information to other devices, or an additional storage device.

Computing device 3300 may include another input device 3311 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 3300 may include a security interface device 3312. Security interface device 3312 may include any device that provides security measures for computing device 3300 such as intrusion detection, biometric validation, security encode or decode, managing access lists, malware detection, or spyware detection.

Computing device 3300 may include an antenna 3313. Antenna 3313 may include any device that translates electrical current to radio waves and/or translates radio waves to electrical current.

Computing device 3300, or a subset of its components, may have any appropriate form factor, such as a server or other networked computing component, a mobile device, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a glass substrate having a thickness extending between a first surface and an opposing second surface thereof, an opening extending from the first surface through the thickness of the glass substrate to the second surface, the opening defining a sidewall of the glass substrate within the opening, a via metallization within the opening and extending from the first surface through the thickness of the glass substrate to the second surface, and a gap between a first region of the via metallization and a first region of the sidewall adjacent the first surface, such that a second region of the via metallization is in direct contact with a second region of the sidewall opposite the gap from the first surface

In one or more second embodiments, further to the first embodiments, the gap extends across a distance of not less than 10 nm between the first region of the via metallization and the first region of the sidewall.

In one or more third embodiments, further to the first or second embodiments, the first region of the via metallization comprises a seed layer of the via metallization, the via metallization further comprising a bulk portion of the via metallization.

In one or more fourth embodiments, further to the first through third embodiments, the apparatus further comprises a first polymer layer on the first surface of the glass substrate and on a coplanar first surface of the via metallization adjacent the first surface of the glass substrate, the first polymer layer extending over and enclosing the gap, and a second polymer layer on the second surface of the glass substrate and on a coplanar second surface of the via metallization adjacent the second surface of the glass substrate, the second polymer layer extending over and enclosing the gap or a second gap within the opening.

In one or more fifth embodiments, further to the first through fourth embodiments, the apparatus further comprises a polypropylene carbonate material layer on a third region of the via metallization and on a third region of the sidewall within the opening.

In one or more sixth embodiments, further to the first through fifth embodiments, the apparatus further comprises a polymeric material having a first portion on the first surface of the glass substrate and a second portion extending into the opening adjacent the first surface, such that the gap is immediately adjacent the second portion within the opening.

In one or more seventh embodiments, further to the first through sixth embodiments, the second portion extends a distance into the opening of not less than 20% of the thickness of the glass substrate.

In one or more eighth embodiments, further to the first through seventh embodiments, the apparatus further comprises a second polymeric material having a portion on the second surface of the glass substrate and a second portion extending into the opening adjacent the second surface.

In one or more ninth embodiments, further to the first through eighth embodiments, the apparatus further comprises a metal pad on or over the second surface of the glass substrate and coupled to the via metallization, such that the gap extends from the second portion of the polymeric material to the metal pad.

In one or more tenth embodiments, further to the first through ninth embodiments, the apparatus further comprises a second polymeric material between the second surface of the glass substrate and the metal pad, such that the gap extends between a region of the second polymeric material and a second region of the via metallization.

In one or more eleventh embodiments, further to the first through tenth embodiments, the apparatus further comprises an integrated circuit (IC) die over the first surface or the second surface of the glass substrate, such that the IC is electrically coupled to the via metallization and the glass substrate is a layer of glass having a thickness of not less than 50 μm, a first length of not less than 10 mm and a second length orthogonal to the first length of not less than 10 mm.

In one or more twelfth embodiments, an apparatus comprises a glass substrate having a thickness extending between a first surface and an opposing second surface thereof, an opening extending from the first surface through the thickness of the glass substrate to the second surface, the opening defining a sidewall of the glass substrate within the opening, a via metallization within the opening of the glass substrate, and an air gap between a first region of the via metallization and a first region of the sidewall within the opening, such that a second region of the via metallization is in direct contact with a second region of the sidewall within the opening, and such that the air gap extends a distance orthogonal to the first region of the sidewall of not less than 100 nm between the first region of the via metallization and the first region of the sidewall.

In one or more thirteenth embodiments, further to the twelfth embodiments, the first region and the second region of the via metallization comprise a seed layer of the via metallization, the via metallization further comprising a bulk portion of the via metallization, and the apparatus further comprising a first polymer layer on the first surface of the glass substrate and on a coplanar first surface of the via metallization adjacent the first surface of the glass substrate, the first polymer layer extending over and enclosing the gap, and a second polymer layer on the second surface of the glass substrate and on a coplanar second surface of the via metallization adjacent the second surface of the glass substrate, the second polymer layer extending over and enclosing the gap or a second gap within the opening.

In one or more fourteenth embodiments, further to the twelfth or thirteenth embodiments, the apparatus further comprises a polymeric material having a first portion on the first surface of the glass substrate and a second portion extending into the opening adjacent the first surface, such that the gap is immediately adjacent the second portion within the opening, and a second polymeric material having a portion on the second surface of the glass substrate and a second portion extending into the opening adjacent the second surface.

In one or more fifteenth embodiments, further to the twelfth through fourteenth embodiments, the apparatus further comprises a polymeric material having a first portion on the first surface of the glass substrate and a second portion extending into the opening adjacent the first surface, such that the gap is immediately adjacent the second portion within the opening, and a metal pad on or over the second surface of the glass substrate and coupled to the via metallization, such that the gap extends from the second portion of the polymeric material to the metal pad.

In one or more sixteenth embodiments, further to the twelfth through fifteenth embodiments, the apparatus further comprises an integrated circuit (IC) die over the first surface or the second surface of the glass substrate, such that the IC is electrically coupled to the via metallization and the glass substrate is a layer of glass having a thickness of not less than 50 μm, a first length of not less than 10 mm and a second length orthogonal to the first length of not less than 10 mm.

In one or more seventeenth embodiments, a method comprises depositing a material layer on a sidewall of an opening that extends through a thickness of a glass substrate from a first surface to an opposing second surface of the glass substrate, forming a via metallization on the material layer within the opening, removing at least a portion of the material layer to form a gap between the sidewall of the opening and the via metallization, and sealing the gap within the opening of the glass substrate.

In one or more eighteenth embodiments, further to the seventeenth embodiments, removing the portion of the material layer and sealing the opening comprises depositing a second material layer on the first surface of the glass substrate and the material layer, and removing the portion of the material layer through the second material layer.

In one or more nineteenth embodiments, further to the seventeenth or eighteenth embodiments, sealing the opening comprises vacuum laminating a second material layer on the first surface of the glass substrate and into at least a portion of the gap between the sidewall of the opening and the via metallization.

In one or more twentieth embodiments, further to the seventeenth through nineteenth embodiments, depositing the material layer on the sidewall of the opening comprises depositing a second material layer on the first surface of the glass substrate and over the opening, forming a metal layer on the second material opening, depositing a conformal layer of the material layer on the sidewall of the opening and on a portion of the second material layer exposed within the opening, and etching a portion of the conformal layer of the material layer and the portion of the second material layer to expose a portion of the metal layer, such that the via metallization is plated from the portion of the metal layer.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a glass substrate having a thickness extending between a first surface and an opposing second surface thereof;
an opening extending from the first surface through the thickness of the glass substrate to the second surface, the opening defining a sidewall of the glass substrate within the opening;
a via metallization within the opening and extending from the first surface through the thickness of the glass substrate to the second surface; and
a gap between a first region of the via metallization and a first region of the sidewall adjacent the first surface, wherein a second region of the via metallization is in direct contact with a second region of the sidewall opposite the gap from the first surface.

2. The apparatus of claim 1, wherein the gap extends across a distance of not less than 10 nm between the first region of the via metallization and the first region of the sidewall.

3. The apparatus of claim 1, wherein the first region of the via metallization comprises a seed layer of the via metallization, the via metallization further comprising a bulk portion of the via metallization.

4. The apparatus of claim 3, further comprising:
a first polymer layer on the first surface of the glass substrate and on a coplanar first surface of the via metallization adjacent the first surface of the glass substrate, the first polymer layer extending over and enclosing the gap; and
a second polymer layer on the second surface of the glass substrate and on a coplanar second surface of the via metallization adjacent the second surface of the glass substrate, the second polymer layer extending over and enclosing the gap or a second gap within the opening.

5. The apparatus of claim 4, further comprising a polypropylene carbonate material layer on a third region of the via metallization and on a third region of the sidewall within the opening.

6. The apparatus of claim 1, further comprising:
a polymeric material having a first portion on the first surface of the glass substrate and a second portion extending into the opening adjacent the first surface, wherein the gap is immediately adjacent the second portion within the opening.

7. The apparatus of claim 6, wherein the second portion extends a distance into the opening of not less than 20% of the thickness of the glass substrate.

8. The apparatus of claim 6, further comprising:
a second polymeric material having a portion on the second surface of the glass substrate and a second portion extending into the opening adjacent the second surface.

9. The apparatus of claim 6, further comprising:
a metal pad on or over the second surface of the glass substrate and coupled to the via metallization, wherein the gap extends from the second portion of the polymeric material to the metal pad.

10. The apparatus of claim 9, further comprising a second polymeric material between the second surface of the glass substrate and the metal pad, wherein the gap extends between a region of the second polymeric material and a second region of the via metallization.

11. The apparatus of claim 1, further comprising:
an integrated circuit (IC) die over the first surface or the second surface of the glass substrate, wherein the IC is electrically coupled to the via metallization and the glass substrate is a layer of glass having a thickness of not less than 50 μm, a first length of not less than 10 mm and a second length orthogonal to the first length of not less than 10 mm.

12. An apparatus, comprising:
a glass substrate having a thickness extending between a first surface and an opposing second surface thereof;
an opening extending from the first surface through the thickness of the glass substrate to the second surface, the opening defining a sidewall of the glass substrate within the opening;
a via metallization within the opening of the glass substrate; and
an air gap between a first region of the via metallization and a first region of the sidewall within the opening, wherein a second region of the via metallization is in direct contact with a second region of the sidewall within the opening, and wherein the air gap extends a distance orthogonal to the first region of the sidewall of not less than 100 nm between the first region of the via metallization and the first region of the sidewall.

13. The apparatus of claim 12, wherein the first region and the second region of the via metallization comprise a seed layer of the via metallization, the via metallization further comprising a bulk portion of the via metallization, the apparatus further comprising:
a first polymer layer on the first surface of the glass substrate and on a coplanar first surface of the via metallization adjacent the first surface of the glass substrate, the first polymer layer extending over and enclosing the gap; and
a second polymer layer on the second surface of the glass substrate and on a coplanar second surface of the via metallization adjacent the second surface of the glass substrate, the second polymer layer extending over and enclosing the gap or a second gap within the opening.

14. The apparatus of claim 12, further comprising:
a polymeric material having a first portion on the first surface of the glass substrate and a second portion extending into the opening adjacent the first surface, wherein the gap is immediately adjacent the second portion within the opening; and
a second polymeric material having a portion on the second surface of the glass substrate and a second portion extending into the opening adjacent the second surface.

15. The apparatus of claim 12, further comprising:
a polymeric material having a first portion on the first surface of the glass substrate and a second portion extending into the opening adjacent the first surface, wherein the gap is immediately adjacent the second portion within the opening; and
a metal pad on or over the second surface of the glass substrate and coupled to the via metallization, wherein the gap extends from the second portion of the polymeric material to the metal pad.

16. The apparatus of claim 12, further comprising:
an integrated circuit (IC) die over the first surface or the second surface of the glass substrate, wherein the IC is electrically coupled to the via metallization and the glass substrate is a layer of glass having a thickness of not less than 50 μm, a first length of not less than 10 mm and a second length orthogonal to the first length of not less than 10 mm.

17. A method, comprising:
depositing a material layer on a sidewall of an opening that extends through a thickness of a glass substrate from a first surface to an opposing second surface of the glass substrate;
forming a via metallization on the material layer within the opening;
removing at least a portion of the material layer to form a gap between the sidewall of the opening and the via metallization; and
sealing the gap within the opening of the glass substrate.

18. The method of claim 17, wherein removing the portion of the material layer and sealing the opening comprises:
depositing a second material layer on the first surface of the glass substrate and the material layer; and
removing the portion of the material layer through the second material layer.

19. The method of claim 17, wherein sealing the opening comprises:
vacuum laminating a second material layer on the first surface of the glass substrate and into at least a portion of the gap between the sidewall of the opening and the via metallization.

20. The method of claim 17, wherein depositing the material layer on the sidewall of the opening comprises:
depositing a second material layer on the first surface of the glass substrate and over the opening;
forming a metal layer on the second material opening;
depositing a conformal layer of the material layer on the sidewall of the opening and on a portion of the second material layer exposed within the opening; and
etching a portion of the conformal layer of the material layer and the portion of the second material layer to expose a portion of the metal layer, wherein the via metallization is plated from the portion of the metal layer.
